(19) United States
(12) Patent Application Publication
(10) Pub. No.: US 2018/0136294 A1
(43) Pub. Date: May 17, 2018

(54) A TYPE OF MR COIL AND ELECTRICAL RESONANT CIRCUITRY COMPRISED OF THE COIL

(71) Applicant: Medlion Healthcare Technologies Ltd., Hefei, Anhui Province (CN)

(72) Inventors: LIGANG LUAN, HEFEI, ANHUI PROVINCE (CN); XIAOBO WANG, HEFEI, ANHUI PROVINCE (CN)

(21) Appl. No.: 15/574,444

(22) PCT Filed: Jul. 27, 2015
(86) PCT No.: PCT/CN2015/085141

§ 371 Date: Nov. 15, 2017

(30) Foreign Application Priority Data
Jan. 21, 2015 (CN) 201510029618.5
Jan. 21, 2015 (CN) 201520041171.9

(51) Int. Cl. G01R 33/34; G01R 33/36; H01F 5/00

(52) U.S. Cl. CPC G01R 33/34092; H01F 5/00; G01R 33/36

(57) ABSTRACT

An imaging coil used for magnetic resonance imaging, comprising at least one conductor (11), the conductor (11) comprising at least one carbon-based nano-material part (12), the conductor (11) also comprising at least one metal conductive part (13); the metal conductive part (13) is disposed on the end of the carbon-based nano-material part (12); and the carbon-based nano-material part (12) occupies 10% or below of the weight of the conductor (11). Using the present imaging coil, the signal to noise ratio of the imaging coil is higher, and the quality of images of a nuclear magnetic resonance imaging device provided with said imaging coil is more precise and accurate.

### FIELD OF THE INVENTION

This application is in the general field of diagnostic medical imaging, and it pertains more specifically to a type of coil and the electrical resonant circuitry comprised of the coil.

### BACKGROUND OF THE INVENTION

In the past few decades the medical imaging modality of Magnetic Resonance Imaging (MRI) has emerged as a technological advance with a large positive impact on modern medical science and practice. This imaging modality is especially useful in a wide variety of soft tissue imaging applications, wherein it can offer an unrivalled range of tissue contrast and diagnostic capability. The further widespread use of this versatile imaging technology would be aided by enhancements to the image quality, including factors such as contrast and resolution that can be obtained with an MRI scanning system without limiting patient comfort or increasing the scan time required to generate a given image.

In general, the image quality of MRI is influenced by several factors. An important factor is the Signal-to-Noise Ratio (SNR) associated with the signal acquisition process and in particular with the signal acquisition/imaging coils that are utilized for Radio Frequency (RF) signal reception. Generally, an increase in the Signal-to-Noise Ratio can be traded off for increased image resolution and/or reduced scan time. RF imaging coils are usually constructed from a highly conductive metal such as copper, and a given coil is often designed for a specific clinical or anatomical application or class of applications. The specifics associated with the coil such as its geometry and overall shape are optimized for the associated clinical application. Modern coils are often constructed in an array configuration consisting of an array of individual coil elements. In general a multiplicity of coil elements is required to cover a desired anatomical volume of interest with a sufficiently high SNR throughout the desired volume.

The SNR of a coil is limited by the electrical resistance associated with the coil, and more specifically by the effective resistance to induced current flow in both the coil and the tissue of interest (often referred to respectively as coil resistance and body resistance), since the noise associated with the coil depends on this effective resistance. The SNR is also limited by how much signal energy is contained relative to noise within the bandwidth of interest around the center frequency associated with the scanner magnet. In the case of arrays of coil elements, inductive coupling between the coil elements can act to further reduce SNR and the design of the array needs to take into consideration such mutual interactions.

Present-day coils are close to their performance limits and given the limitations of the current state of the art in RF imaging coils for MRI, there is an unmet need for enhanced imaging coils that can acquire more signal with less noise.

The present invention addresses this need and discloses a method and apparatus for RF imaging coils for MRI that can provide enhanced levels of Signal-to-Noise-Ratio (SNR) performance as compared to conventional imaging coils.

### SUMMARY OF THE INVENTION

To overcome the above mentioned defects, the purpose of this invention is to provide a type of MR imaging coil with enhanced intrinsic SNR.

The present invention discloses an imaging coil element for magnetic resonance imaging, which comprises at least one electrical conductor of known dimensions constructed as a compound electrical conductor, said compound electrical conductor comprised of at least one conductor comprising carbon-based nanomaterial part, and at least one metallic conductor part, with the metallic conductor part attached to the ends of the nanomaterial part. The nanomaterial represents a weight fraction of 10% or less of the compound conductor.

Preferably, the said compound conductor comprises a main metallic body, on which the above-said metallic conductor part and nanomaterial part are placed. The main metallic body has a thickness of at least twice the skin depth in that metal at the frequency of operation.

Preferably, there are one or multiple folds in the center of the main metallic conductor body, whereas the folding lines are parallel to the layout of the carbon-based nanomaterial, so that with each folding the main metallic conductor body covers the carbon-based nanomaterial part.

Preferably, the compound conductor includes a carbon-based nanomaterial part lying within a-hollow-tube shaped main metallic conductor body, with the metalized ends of the nanomaterial attached to the metallic tube body just within each rim or edge of the tube.

Preferably, the imaging coil can also be constructed from multiple windings of a compound electrical conductor built around a support structure.

Preferably, capacitors are inserted among breaks of the multiple-winding conductors to minimize the resistance of the conductor.

Preferably, the carbon-based nanomaterial includes a distribution of ferromagnetic nanoparticles.

Preferably, the distribution of ferromagnetic nanoparticles in the nanomaterial conductor, expressed as a weight fraction of the compound conductor, lies in the range between 0.1% and 8%.

Preferably, the distribution of ferromagnetic nanoparticles in the nanomaterial conductor, expressed as a weight fraction of the compound conductor, lies in the range between 0.1% and 5%.

Preferably, the carbon-based nanomaterial comprises nanotube, buckypaper and graphene.

Preferably, the said metallic conductor part is formed through electroplating at the ends of the carbon-based nanomaterial part.

Preferably, the said metallic conductor part is formed by applying conductive silver paste at the ends of the carbon-based nanomaterial part.

Preferably, working frequency lies in the range of 2 MHz-800 MHz.

Preferably, the metallic conductor part has a length of 2 mm-35 mm.

Preferably, the configuration of the carbon-based nanomaterial comprises a ribbon-like geometry, a sheet-like geometry, a rectangle-like geometry, a string-like geometry, or a yarn-like geometry of one of multi-pairs of twist.

Preferably, the metallic conductor part has a thickness of 3-5 times of the skin depth of that metal.

Preferably, the density of the metallic conductor part is at least 10 times that of the carbon-based nanomaterial.

In the mean time, the present invention discloses a type of electrical resonant circuitry near the frequency of interest, comprised of capacitors, inductors and the above mentioned imaging coil element that are interconnected with each other.

Preferably, the said resonant circuitry comprises of a transmit blocking unit connected to the said imaging coil.

Preferably, the said resonant circuitry comprises of a preamplifier unit, connected to the said imaging coil.

Preferably, a plurality of imaging coil elements are superposed to form an imaging array.

Compared to the existing technology, the technology disclosed in the present invention has the following benefits:

1) Enhanced Signal-to-Noise Ratio for imaging coils. Magnetic Resonance Imaging systems with the said imaging coils could scan with improved image quality.

2) The rate of increase with frequency of the inductive reactance of the imaging coil is smaller.

3) The intrinsic resistance to RF current flow in the metallic conductor is reduced.

4) The redistribution of some of the charge flow away from the outer surface of the metallic conductor results in reduced self-capacitance of the conductor

### BRIEF DESCRIPTION OF THE DRAWINGS

FIG. 1a is a schematic illustration of one structure of the imaging coil of the present invention.

FIG. 1b is another schematic illustration of one structure of the imaging coil of the present invention.

FIG. 2a is a schematic illustration of the imaging coil in a main metallic conductor body of the present invention.

FIG. 2b is a schematic illustration of another imaging coil in a main metallic conductor body of the present invention.

FIG. 2c is a schematic illustration of the third imaging coil in a main metallic conductor body of the present invention.

FIG. 3 is a schematic representation of an equivalent circuit for the electrical resonant circuitry formed by the imaging coil, capacitors and inductors of the present invention.

FIG. 4 is a schematic representation of the electrical resonant circuitry formed by multiple turns of a compound electrical conductor.

FIG. 5 is a schematic illustration of the electrical resonant circuitry formed by an imaging coil element having a generally rectangular geometry.

FIGS. 6a, 6b, 6c and 6d are schematic depictions of various geometries of imaging coils of the present invention comprising compound electrical conductors.

FIG. 7 is a schematic illustration of the geometry of an imaging coil array of the present invention comprising compound electrical conductors.

### NOTES

10—imaging coil
11—electrical conductor
12—carbon-based nanomaterial part
13—metallic conductor part
14—main metallic conductor body
20—electrical resonant circuitry
21—circuit board

### DETAILED DESCRIPTION OF EMBODIMENTS OF THE INVENTION

Advantages of the present invention are further detailed below with figures and embodiments.

Because of the extremely unreasonable cost of obtaining the carbon-based nanomaterial used in building the imaging coils, coils in the present invention deploy nanomaterial only on a small scale. Particularly, the imaging coils include at least one conductor, with one or multiple such conductors forming the coil. Each conductor comprises a nanostructured carbon-based nanomaterial part or related variations showing ballistic charge transport characteristics. The conductor also includes at least one metallic conductor part, deposited at the ends of the carbon-based nanomaterial part, serving as the connector between the carbon-based nanomaterial and external electrical components. With the introduction of the metallic conductor part, part of the conductivity of the nanomaterial is replaced by the metallic conductor part. As a result, the use of carbon-based nanomaterial could be lessened to 10% or even lower of the total weight of the conductor, which means significantly lowered cost for obtaining the carbon-based nanomaterial. Subsequently, the metallic conductor part turns out to serve as the main conductor in the present invention. While nanomaterial based conductor doesn't exhibit skin effects, whereas resistance increases with the increase of frequency, the compound conductor formed by placing metallic conductor part at the ends of the carbon-based nanomaterial part does show skin effect, which prevents resistance from increasing with the increase of the frequency.

In order to make sure that the carbon-based nanomaterial takes a weight fraction of less than 10% of the total compound conductor, the metallic conductor part can be chosen as such that the mass density per unit length of the metallic conductor part is at least ten times larger than the mass density per unit length of the nanomaterial. Therefore, while the metallic conductor may take less volume than the nanomaterial does in the compound conductor, it can take 90% or above in mass. It's obvious that metals such as copper, gold or silver can meet such requirements.

In the meanwhile, it has been found that a metallization length of between approximately 2 mm and 35 mm, and a metallization thickness of at least several microns of the metallic conductor part, is appropriate in order to yield good electrical connectivity and mechanical robustness in electrical connections (such as solder joints) between the nanomaterial conductor part and metallic conductor part or other electrical components or circuit elements. Such overall considerations can help to set a range for process parameters (such as current flow in an electroplating process) to generate the desired metallization length and thickness at the ends of the nanomaterial conductor.

The nanostructured carbon-based nanomaterial can include carbon nanotube, buckypaper or graphene.

In the above embodiment, the nano-metal compound electrical conductor has over a range of frequencies of interest a resistance (real part of impedance) whose rate of increase with frequency is smaller than that of a similarly dimensioned electrical conductor constructed only of metal. Additionally, the compound electrical conductor can also have, over a range of frequencies of interest, an inductive reactance (imaginary part of impedance) whose rate of increase with frequency is smaller than that of a similarly dimensioned electrical conductor constructed only of metal.

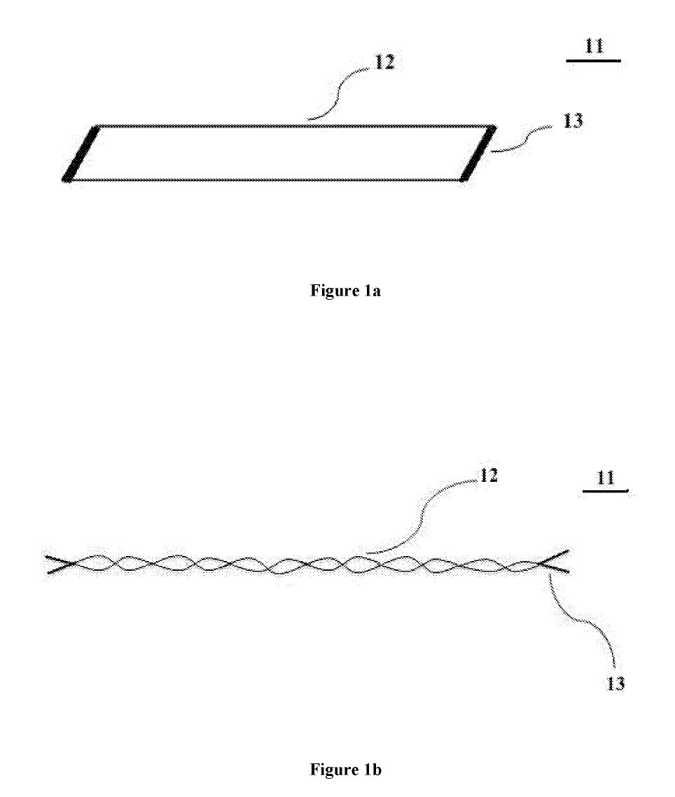

A schematic illustration of a preferable embodiment of the imaging coil is shown in FIG. 1a. The nanomaterial conductor part 12 comprised in compound conductor 11 takes a ribbon-like form. The ribbon can be composed of a multitude of individual nanotubes agglomerated into bundles, possibly in hierarchical manner, under the influence of intermolecular forces (van der Waals forces). The individual nanotubes can be either single walled or multi walled nanotubes. Furthermore in some cases the ribbon can itself comprise multiple layers of thinner ribbons, and the term “ribbon” here and elsewhere is taken to include such structures, without limitations. In this schematic figure, metallic conductor part 13 are deposited at both ends of the nanomaterial conductor 12 and are depicted in darkened form for purposes of illustration. FIG. 1b is another schematic illustration of nanomaterial conductor part 12 in the form of a twisted or braided yarn comprising a pair of threads or strings. The metalized ends 13 of the nanomaterial conductor part 12 are depicted in darkened form for purposes of illustration. It's understandable to professionals in this industry that the above two cases of carbon-based nanomaterial conductor are only schematic illustrations, with other forms of the nanomaterial such as sheet, rectangle, or string apply to the present invention.

In the above two cases, the carbon nanomaterial conductor 12 can be connected or attached electrically to the metallic conductor 13 by any of several metallization methods. In one embodiment, the ends of the nanomaterial conductor part 12 can be electroplated with copper, gold, or other metal to form the metallic conductor part 13, while in an alternate embodiment electrically conducting silver paste can be applied to the ends of the nanomaterial conductor part 12 to form the metallic conductor part 13. In the case when silver paste is used instead, as the silver paste (which usually contains a relatively high proportion of silver particles dispersed in a resin) dries or cures, in some cases (depending on the type of resin used in the paste) at temperatures above normal room temperatures in an oven, the silver particles form a continuous matrix forming a connection with the carbon nanomaterial conductor part 12. In yet another alternate embodiment, electrodes comprising materials such as palladium or platinum can be deposited at the ends of the nanomaterial conductor part 12 to form the metallic conductor part 13 by a sputtering process. With the forms of electrical connection described in the above, the ends of the nanomaterial conductor are effectively turned into metal-covered or metallic electrode ends that can then be directly soldered on to conventional metallic junctions, electrical conductors or electronic components (for example, resistors, diodes, inductors, etc.) for incorporation into an electrical circuit.

Furthermore, the carbon nanomaterial conductor part 12 is further specifically characterized by having a distribution of ferromagnetic nanoparticles. The presence of ferromagnetic particles in equipment used in Magnetic Resonance Imaging is counterintuitive, since usually great pains are taken to avoid such materials in the presence of the MRI scanner due to the possibility of distortion of the magnetic field of the MRI scanner. Nevertheless, the inventor has determined that with the ferromagnetic weight fraction as described below, the distribution of ferromagnetic nanoparticles in the nanomaterial can actually be advantageous. Specifically, the ferromagnetic nanoparticles can act to channel the local RF flux due to current flow in the compound conductor 11 and create a central zone or pathway within the conductor 11 for RF current flow, thereby redistributing RF current flow in the conductor 11. This has two benefits: (i) it reduces the intrinsic resistance to RF current flow in the conductor 11, and (ii) the redistribution of some of the charge flow away from the outer surface of the metallic conductor 11 results in reduced self-capacitance of the compound electrical conductor 11. Consequently the RF electric field outside the compound electrical conductor 11 is reduced, and this helps to mitigate coil loading effects due to electric field-driven RF currents in the subject tissue being imaged. Specifically, this fraction of ferromagnetic nanoparticles is chosen to be in the range of 0.1%-8% by weight of the compound conductor 11, and more preferably in the range 0.1%-5%. As a result, The compound electrical conductor 11 can have significantly lowered resistive loss and lowered self-capacitance and therefore achieves much enhanced SNR at the 2 MHz-800 MHz working frequency.

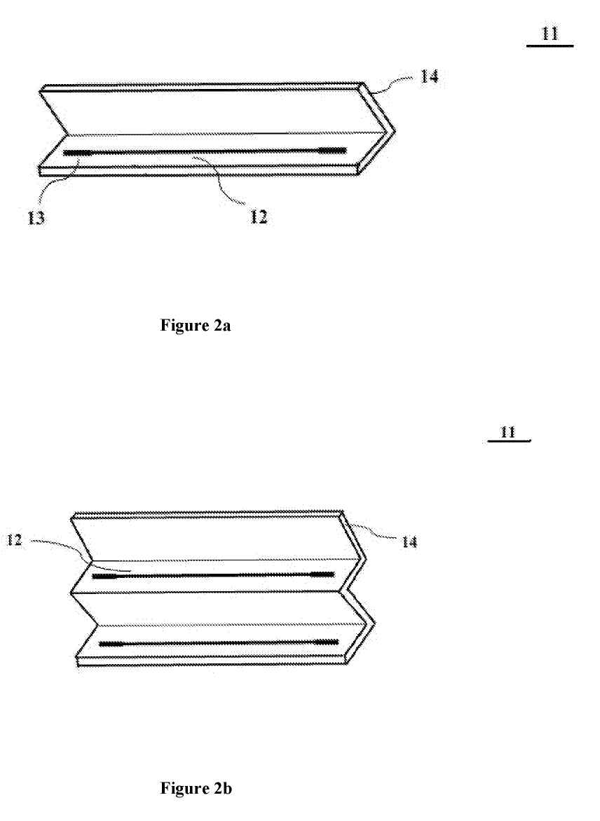

In FIG. 2a, the compound conductor 11 comprises a main metallic conductor body 14, with the metallic conductor part 13 and the carbon nanomaterial part 12 laid on the main metallic conductor 14, whereas the combination of conductors 12, 13 and 14 forms the imaging coil 10. In the FIG. 2a embodiment, the metallic conductor part 13 is attached to the main metallic conductor body 14, with the metallic conductor 14 taking a partially folded structure for clarity. In practice the metallic conductor body 14 is fully folded and can completely cover the nanomaterial conductor part 12 and the metalized ends 13. To make sure of the skin effect, the main metallic conductor body 14 is shown as having a thickness denoted by t, whereas it is desirable that this thickness t is at least twice as large as the skin depth

$$δ = \sqrt{\frac{Z ρ}{ωμ}} ,$$

where p is the resistivity of the metal, μ is its magnetic permeability and ω is the circular frequency associated with the radio frequency of interest. Still more preferably, the thickness t is approximately between 3 and 5 times as large as the skin depth δ. The work frequency hereby referred to is the work frequency of the metal, namely 2 MHz-800 MHz, which is also the range of the frequency for magnet resonance imaging.

In an even more preferable embodiment as shown in FIG. 2b, there are multiple folds in the middle of the main metallic conductor body 14, whereas the folding lines are parallel to the layout of the carbon nanomaterial part 12 so that with each folding the metallic conductor body 14 could completely cover the nanomaterial part 12. In the case of multiple folds, one combination of nanomaterial part 12 and metallic conductor part 13 could be placed between each fold. While only a doubly folded accordion structure is shown in the figure for purposes of clarity, a multiplicity of combinations of folds and conductor 11 can be used, as convenient for the application. Such variations are conceived and intended to be within the scope of the present invention. While an accordion-like two folds is shown in FIG. 2b as a specific example, other folded structures and folding patterns may be developed to construct the compound conductor and used as may be advantageous and/or convenient for the application while remaining within the scope of the present invention.

An alternate embodiment of compound conductor is shown in FIG. 2c, where nanomaterial conductor part 12 with metalized ends 13 lies within a hollow metallic tube body 14 and is attached (at its ends) to the metallic tube body 14 just within each rim or edge of the tube 14. This structure also takes advantage of skin effect, with the metallic surface serving as the main electrical conductor.

Apart from the above embodiments, imaging coil can also be constructed from multiple windings of a compound electrical conductor built around a support structure, with capacitors inserted among multiple-winding conductors to minimize to the resistance of the conductor.

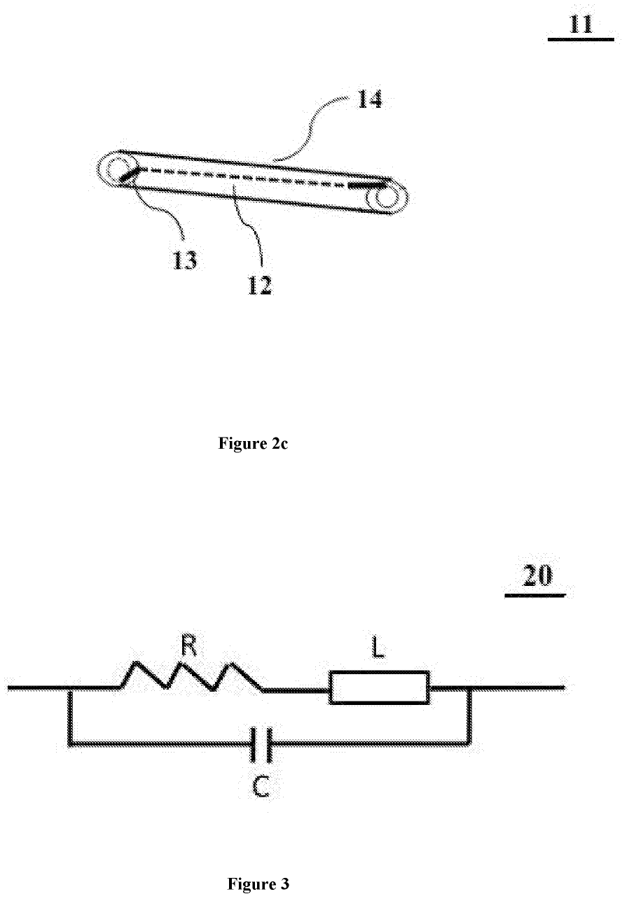

An imaging coil from any of the above embodiments can be connected to an electrical resonant circuitry. As shown in FIG. 3, the electrical resonant circuit 20 comprises a resistor R in series with inductor L, this combination being in parallel with a capacitor C. Here the parametric values of R and L may be determined from measurements at low frequencies, in the range of thousands of Hz.

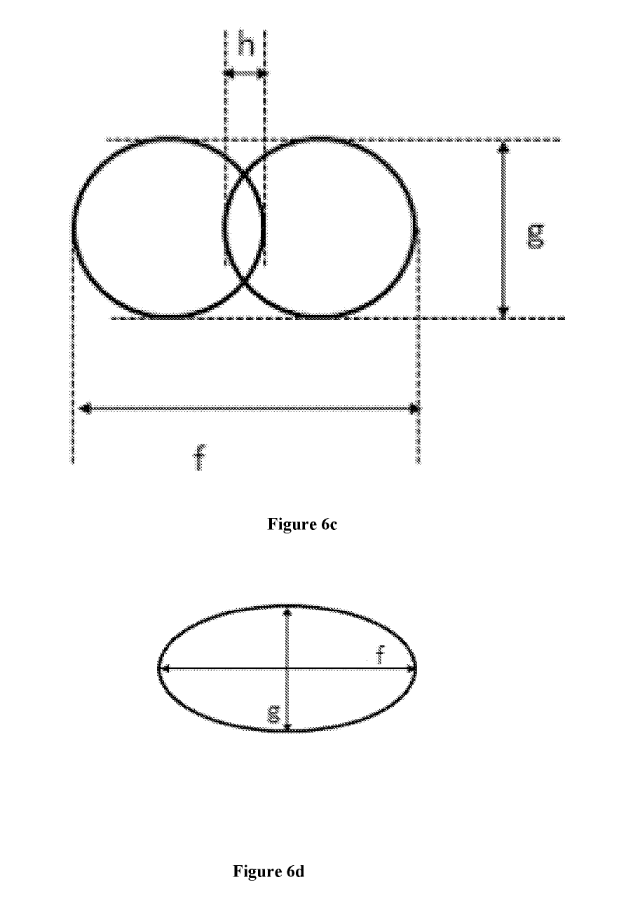

In the simplest model, at a frequency ω, the complex impedance of the circuit shown in FIG. 6 can be written as

$$Z = \frac{{RX}_{C}^{2} - {jX}_{C} ( {R}^{2} + {X}_{L} ( {X}_{L} - {X}_{C} ) )}{{R}^{2} + {( {X}_{L} - {X}_{C} )}^{2}} \qquad ( 1 )$$

where X_{L}=ωL and

$${X}_{C} = \frac{2}{ω C}$$

are the magnitudes of the inductive and capacitive reactance respectively associated with inductor L and capacitor C. In the frequency range generally of relevance to Magnetic Resonance Imaging and for typical conductor lengths, in terms of magnitudes the capacitive reactance is much larger than both the inductive reactance and the resistance, X_{C}»X_{L} and X_{C}»R, so the imaginary part X₁ of the impedance (or the effective/measured inductance of the conductor at frequency ω) may be written as

X₁1^{H}=Im(¹⁸Z)|(X₁LXᵢC^{T}2)/(R^{T}2+|(X₁L|XᵢC)|^{T}2)˜X₁L(1+(2XᵢL)/X₁C) (2)

It is to be noted that X₁ is measured as the apparent or effective inductive reactance of the conductor at frequency ω. Likewise, the real part X_{R} of the impedance, or the effective resistance, can be written

X₁R^{N}−Re(^{N}Z)=(RX₁C^{T}2)/(R^{T}2+|(X₁L|XᵢC)|^{T}Z)˜R(1+(ZXᵢL)/X₁C) (3)

As a function of frequency, X_{R} is quadratic in ω, and we find for its derivative

$$\frac{{dX}_{R}}{d ω} ≅ 4 RCL ω \qquad ( 4 )$$

Likewise, the rate of change of inductive reactance with frequency (from equation (2)) is also proportional to the self-capacitance value C. For compound electrical conductor configurations (as described in the form of several examples as detailed in the foregoing), the value of L can be quite similar to that obtained from a metallic conductor of similar overall dimensions as the compound conductor. However, the value of C or self-capacitance is significantly reduced for the compound conductor as compared to that for a metallic conductor of similar overall dimensions, owing to its modified charge transport characteristics. Likewise, the parameter R can also be smaller for the compound conductor as compared to that for a metallic conductor of similar overall dimensions. Thus, the rate of increase of the effective resistance X_{R} as a function of frequency ω is smaller for a given compound electrical conductor (constructed according to the teachings of the present invention) than that for a metallic conductor (constructed of metal only) of similar overall dimensions. Likewise, the rate of increase of the inductive reactance X₁ as a function of frequency ω is smaller for a given compound electrical conductor (constructed according to the teachings of the present invention) than that for a metallic conductor (constructed of metal only) of similar overall dimensions. These features persists either directly for the imaging coil or when the coil is incorporated into part of an electrical resonant circuit.

According to the teachings of the present invention, such a resonant circuit 20 can generally be formed by incorporating a multitude of loops in a patterned arrangement, constituting an overall signal reception/transmission structure for reception and/or transmission of electromagnetic signals for MRI. Such tuning and impedance matching circuitry is familiar to those skilled in the art. In the case of an imaging coil being used only for signal reception, a separate signal transmit coil is used to transmit RF signals to the sample/subject of interest. In this case, RF blocking circuitry to detune the signal reception imaging coil during the RF transmit phase is incorporated in active or passive forms or both, usually by the use of appropriate diodes such as PIN diodes as is familiar to those skilled in the art.

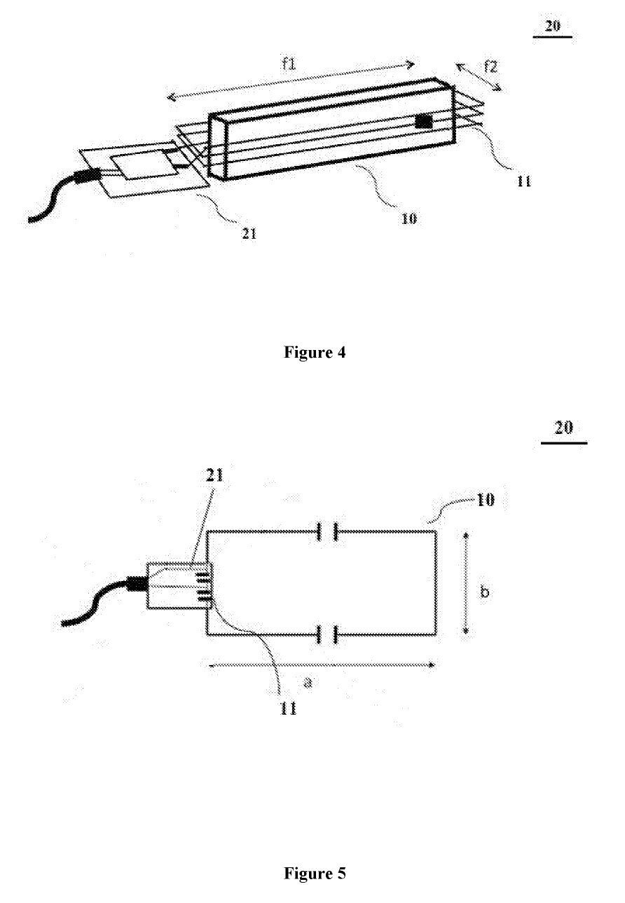

FIG. 4 shows an example of imaging coil 10 constructed from multiple windings of a compound electrical conductor connected to an electrical resonant circuitry 20. The ends of imaging coil 10 are attached to a circuit board 21. Such a circuitry serves to turn the imaging coil into a resonant circuit at the desired frequency of operation. The construction of the tuning/matching circuitry is standard and is known to those skilled in the art. Further, the circuitry 20 can include other elements such as transmit blocking circuitry (in case the imaging coil is used exclusively to only receive RF signals). In one embodiment where the imaging coil is used only for reception of RF signals, the circuitry 20 can include a preamplifier unit for preamplification of received RF signals. The overall dimensions of the imaging coil 10 are indicated in FIG. 4 in terms of length f1 and width f2. The ratio of f1/f2, or the aspect ratio, is a dimensional parameter associated with the imaging coil 10. While the schematic illustration in the figure depicts approximately 3 windings or turns of conductor 11, more generally such a coil can comprise approximately one or more turns, as may be convenient for a given application. While the dimensions f1 and f2 can be in the range of tens of centimeters in some embodiments, in others they can be in the range of centimeters. In one preferred embodiment, the aspect ratio f1/f2 is at least 1.5 or larger. While a generally rectangular cross section for the windings is shown in the figure, in other embodiments the winding cross section can be more generally curvilinear with arcuate sections. In such more general cases the ratio of longest cross sectional dimension to shortest cross sectional dimension is still referred to as the aspect ratio f1/f2.

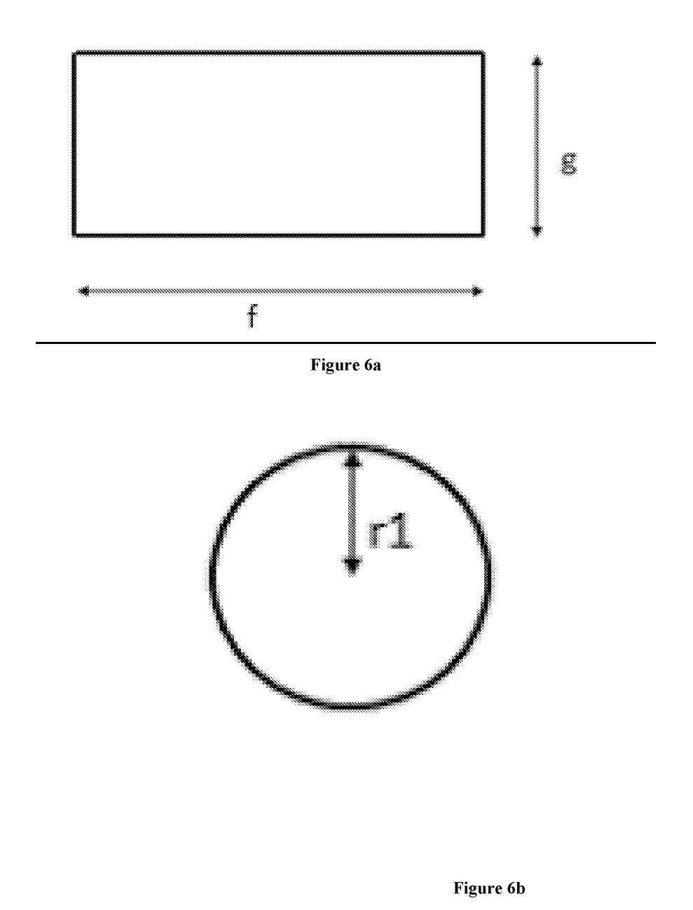

FIG. 5 illustrates an electrical resonant circuitry 20 comprising imaging coil 10 of the present invention in further detail. In FIG. 5, the imaging coil 10 has a rectangular form with rectangle dimensions a and b (together describing the form factor) and can further include capacitors. As illustrated, the capacitors are inserted into gaps between segments of imaging coil 10. Capacitors can serve to reduce electric fields around the coil 10 and thence lead to reduced effective electrical resistance associated with the imaging coil 10. Although two capacitors are shown in this figure, the number of such capacitors in a given imaging coil of the present invention can also be larger or smaller depending on desired performance.

Terminal ends of compound electrical conductors 11 can be connected to circuit board 21. Circuit board 21 can include components for tuning the coil 10 to a desired resonant frequency and for matching the coil 10 to a desired impedance value. Capacitors are shown schematically on circuit board 21. Also shown on the circuit board are electrical traces. An electrical board-mount RF connector (such as, for example, an SMA connector) can attach to circuit board 21, and coaxial cable can connect the circuit board 21. Coaxial cable can carry received RF signals back to an MRI scanner possibly by way of a preamplifier (not shown) for early-stage signal amplification, as is known to those skilled in the art. Circuit board 21 can further include other electrical components (not shown), such as other capacitors and inductors and PIN diodes for example for purposes of coil detuning during MRI system transmit, as is well known in the art and associated literature.

A resonant structure 20 in the form of a multiplicity of distinct imaging coil elements 10, in some cases possibly including suitable circuit interconnections such as mutual inductors that may be needed to reduce inter-element electromagnetic coupling, can also be built in order to receive signals in the form of a phased array construction. The electronic circuitry 20 associated with such an array imaging coil 10 can include elements such as low impedance preamplifiers, which are often used to decouple or reduce the coupling between imaging coil elements in the array imaging coil 10. The methodologies for building such phased array configurations are known to those skilled in the art. Such multiple-element phased array constructions are useful in the acquisition of signals for parallel imaging and to cover an entire anatomical region of interest, which can result in faster scan times, improved Signal-to-Noise Ratio within a region of interest, or a combination of these enhancements. Likewise, the imaging coil 10 can include circuit elements or sub-circuits that are intended to block or decouple the receive coil elements from the RF transmit pulse during the transmit phase of the imaging sequence.

Since the nanomaterial-based constructions and embodiments of imaging coils described here can generally be made to yield a smaller rate of increase of the effective resistance X_{R} as a function of frequency ω than that for an imaging coil constructed with metallic conductors alone (constructed of metal only) of similar overall dimensions, and further have a reduced self-capacitance, resistive losses are mitigated in both the imaging coil 10 as well as in the tissue being imaged. Consequently an imaging coil 10 of the present invention will correspondingly receive signals and generate images with a larger Signal-to-Noise Ratio (SNR) than would be possible from an imaging coil of similar form factor constructed with metallic conductors only.

Likewise the imaging coil element 10 disclosed herein will also have a larger quality factor Q than would be possible with an imaging coil of similar form factor constructed with metallic conductors only, even in the presence of coil loading. In the case where the imaging coil 10 and associated circuitry is built to support transmission of electromagnetic signals, the imaging coil 10 will correspondingly be able to transmit electromagnetic signals more efficiently, with less loss, than would be possible from an imaging coil with similar form factor constructed with metallic conductors only. Specifically, tuning circuitry 20 can be used to tune the imaging coil 10 of the present invention constructed with compound electrical conductors to preferentially receive RF electrical signals in a relatively narrow bandwidth around the center frequency associated with the scanner magnet, and to match the effective coil 10 impedance to a specified preamplifier source impedance for optimal signal transfer to the Mill scanner. The tuning may be accomplished by any known tuning method. The sharpness of the tuning is measured by the Quality Factor Q, defined as the ratio of center frequency to bandwidth at half-maximum. A sharper tuning or higher Q factor leads to relatively more signal energy being captured by the coil. Given an imaging coil 10 of the present invention employing compound electrical conductors that has a Quality Factor value Q_{c} (measured in the presence of coil or tissue loading), one can define a corresponding Quality Factor Qₜ (measured in the presence of coil or tissue loading), for a conventional coil with completely metallic conducting elements (for example made of copper) that has closely identical form factor or overall dimensions to the former coil. By using the compound electrical conductor-based construction as taught herein, compound electrical conductor-based coil 10 can be built so as to possess a ratio Q_{c}/Qₜ that can be at least 1.05, extending to at least 1.1, and even at least 1.2, reflecting quality gains that can be more than 20%.

In order to prevent signal pickup by the coil during system transmit mode, PIN diodes may be included in the circuitry 20 at various locations, either as part of a board for the tuning circuitry for the coil, or at the breaks in the conducting element 11. In some cases the PIN diodes can be actively turned on by application of a suitable bias voltage that can then activate circuitry that serves to block signals in the coil during system transmit mode.

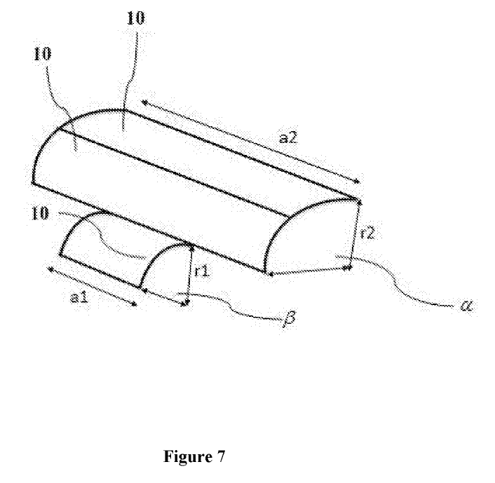

Examples of imaging coil element form factors are provided in FIGS. 6a, 6b, 6c, 6d and 7. A coil element 10 in the form of a rectangular loop with sides of length f and g is shown schematically in FIG. 6a. In this case these dimensions together define the overall form factor. A coil element 10 in the form of a circular loop of radius r1 is shown schematically in FIG. 6b; in this case the overall form factor is defined by this single number r1. The schematic illustration in FIG. 6c shows a coil array 10 formed from an overlapped pair of separate circular elements, with overall end-to-end dimensions f and g and overlap h. In this case the overall form factor is defined by the set (f, g, h) with the associated geometrical meaning of each dimension in this set. FIG. 9d schematically depicts a coil element 10 in an elliptical configuration, with ellipse major and minor axes of lengths f and g respectively. In this case the overall form factor is defined by the set (f, g) with the associated geometrical meaning of each dimension in this set.

FIG. 7 shows an example of an imaging coil array 10 of more complex geometry, schematically depicted in that figure as comprising of multiple imaging coil elements 10, each formed from a combination of compound electrical conductors 11 disposed in both straight and arcuate forms. In this example, provided for exemplary schematic illustration purposes only, the lengths a1 and a2 associated with straight sections, radii r1 and r2 of the arcuate sections, and the angles α and β associated with the arcuate sections collectively define the overall form factor of the imaging coil array 10.

It is worth noting again that the depictions in FIGS. 6a, 6b, 9c, 9d and 7 explaining overall form factor are schematic illustrations intended to be as such for purposes of clarity, and details such as capacitors distributed along the length of the coil, gaps in the conductor where other electrical or electronic components or circuitry may be attached, circuit boards, other circuitry and the like are not explicitly shown. The examples of geometries and form factors shown in these figures are provided as examples for illustrative purposes only and any variations or alternative coil element geometries can also, without any limitation, be described in terms of a set of form factors similar to the exemplar illustrations provided here. The coil element shapes can take on a wide variety of forms, and structures or elements could be disposed in a concave, convex or saddle-type spatial arrangement, or indeed any arbitrary shape as may be convenient for a given application. Coil elements could share elements or not, be overlapped or not, and so on in various multi-channel imaging array configurations. Thus in general the form factor of a coil element is taken to be a set of generalized dimensional numbers that describe overall geometry, for example including both linear and angular dimensions, as well as other similar geometrical quantities such as for instance solid angles where appropriate, together with their associated geometrical meanings that in totality describe the overall size and shape of the imaging coil element or array.

It's understandable that any of the above embodiments of imaging coils and electrical resonant circuitry comprising the imaging coils is not confined to be used in the medical device sector. They are also applicable to others fields such as telecommunication and electronics, where coils are used for conductors. The scope of application of the present invention listed herein is only illustrative and shall not be deemed as constraints to the present invention.

It's worth noting that multitude of other variations and alternative arrangements can be devised by those skilled in the art without departing from the spirit and scope of this description, and the appended claims are intended to cover such modifications and arrangements. The specific embodiments described in the foregoing are for illustrative purposes and the practice of the invention is limited only by the attached claims. Thus, while the information has been described above with specific detail in connection with what is presently deemed to be the most practical and preferred aspects, it will be apparent to those of ordinary skill in the art that numerous modifications, including, but not limited to, form, function, manner of operation and use can be made without departing from the principles and concepts taught herein.

1: An imaging coil element for magnetic resonance imaging, where the imaging coil element comprises at least one electrical compound conductor comprising at least one carbon-based nanomaterial part, wherein
there is at least one metallic conductor part,
the metallic conductor part being disposed at the ends of the carbon-based nanomaterial part,
the carbon-based nanomaterial part represents a weight fraction of 10% or less of the compound conductor.

2: The imaging coil element of claim 1, wherein
the electrical compound conductor comprises a main metallic conductor body, on which the metallic conductor part and the carbon-based nanomaterial part are laid,
the main metal conductor body has a thickness of at least twice the skin depth in that metal at the frequency of operation.

3: The imaging coil element of claim 2, wherein
there are one or multiple folds in the center of the main metal conductor body, whereas the folding lines are parallel to the layout of the carbon-based nanomaterial part so that with each folding the main metal conductor body covers the carbon-based nanomaterial part.

4: The imaging coil element of claim 1, wherein
the compound conductor includes a carbon-based nanomaterial part lying within a hollow-tube-shaped main metal conductor body, with the metalized ends of the nanomaterial attached to the metallic tube just within each rim or edge of the tube.

5: The imaging coil element of claim 1, wherein
the imaging coil is constructed from multiple windings of a compound electrical conductor built around a support structure.

6: The imaging coil element of claim 1, wherein
capacitors are inserted among breaks of the multiple-winding conductors to minimize the resistance of the conductor.

7: The imaging coil element of claim 1, wherein
the carbon-based nanomaterial includes a distribution of ferromagnetic nanoparticles.

8: The imaging coil element of claim 7, wherein
the distribution of ferromagnetic nanoparticles in the nanomaterial conductor, expressed as a weight fraction of the compound conductor, lies in the range between 0.1% and 8%.

9: The imaging coil element of claim 8, wherein
the distribution of ferromagnetic nanoparticles in the nanomaterial conductor, expressed as a weight fraction of the compound conductor, lies in the range between 0.1% and 5%.

10: The imaging coil element of claim 1, wherein
the carbon-based nanomaterial comprises nanotube, buckypaper and graphene.

11: The imaging coil element of claim 1, wherein
the metallic conductor part is formed by electroplating at the ends of the carbon-based nanomaterial part.

12: The imaging coil element of claim 1, wherein
the metallic conductor part is formed by applying electrically conducting silver paste to the ends of the nanomaterial conductor part.

13: The imaging coil element of claim 1, wherein
the work frequency has a range of 2-800 MHz.

14: The imaging coil element of claim 1, wherein
the metallic conductor part has a length of 2 mm-35 mm.

15: The imaging coil element of claim 1, wherein
the configuration of the carbon-based nanomaterial comprises a ribbon-like geometry, a sheet-like geometry, a rectangle-like geometry, a string-like geometry, or a yarn-like geometry with one or multiple pairs of twist.

16: The imaging coil element of claim 1, wherein
the thickness of the metallic conductor part is three to five times that of the skin depth thickness of the metal in its work frequency.

17: The imaging coil element of claim 1, wherein
the metallic conductor has a mass density per unit length that is at least ten times larger than the mass density per unit length of the nanomaterial.

18: An electrical resonant circuitry, wherein
the imaging coil element of claim 1 is included, together with interconnected capacitors and inductors.

19: The electrical resonant circuitry of claim 18, wherein
the circuitry included a transmit blocking element, connected to the imaging coil.

20: The electrical resonant circuitry of claim 18, wherein
the electronic circuitry includes a preamplifier for augmenting signal gain.

21: The electrical resonant circuitry of claim 18, wherein
at least one imaging coil element is one of a plurality of imaging coil elements superposed in an imaging array.
